(19) United States
(12) Patent Application Publication
(10) Pub. No.: US 2014/0322655 A1
(43) Pub. Date: Oct. 30, 2014

(54) STAGE APPARATUS, LITHOGRAPHY APPARATUS, AND METHOD OF MANUFACTURING ARTICLE

(71) Applicant: CANON KABUSHIKI KAISHA, Tokyo (JP)

(72) Inventors: Toshihiko Nishida, Utsunomiya-shi (JP); Hideki Ina, Tokyo (JP); Wataru Yamaguchi, Utsunomiya-shi (JP)

(73) Assignee: CANON KABUSHIKI KAISHA, Tokyo (JP)

(21) Appl. No.: 14/263,902

(22) Filed: Apr. 28, 2014

(30) Foreign Application Priority Data
Apr. 30, 2013 (JP) 2013-096011

(51) Int. Cl. H01J 37/20; F16M 13/02

(52) U.S. Cl. CPC H01J 37/20; F16M 13/022
USPC 430/296; 250/492.3; 269/55; 269/58

(57) ABSTRACT

A stage apparatus includes first, second, third, and fourth stages arranged along a plane defined by first and second axes orthogonal to each other, each of the first to fourth stages holding an article and being subjected to scanning along the plane, and a controller configured to control the scanning of the first to fourth stages in synchronization such that a pair of the first and second stages and a pair of the third and fourth stages are respectively positioned symmetrically to each other with respect to the first axis and a pair of the first and third stages and a pair of the second and fourth stages are respectively positioned symmetrically to each other with respect to the second axis.

### BACKGROUND OF THE INVENTION

1. Field of the Invention

The present invention relates to a stage apparatus including a plurality of stages, a lithography apparatus, and a method of manufacturing an article.

2. Description of the Related Art

In a stage apparatus, the reaction force resulting from the movement of a stage caused by an actuator can adversely affect the stage positioning accuracy through vibration or deformation of the apparatus. The reaction force depends on the product of a mass (moment of inertia) and an acceleration (angular acceleration) of the stage (object to be driven). Therefore, as the (angular) acceleration or the wafer size increases to improve productivity, the reaction force can also increase.

A known technique for reducing the effect of reaction force is to provide a counterweight mechanism or a reaction force cancellation mechanism in a stage apparatus including a plurality of movable stages (Japanese Patent Nos. 3919782 and 4292573).

The stage apparatuses discussed in Japanese Patent Nos. 3919782 and 4292573 include a counterweight mechanism or a reaction force cancellation mechanism, and this often leads to an increase in size of the apparatuses. Furthermore, as the acceleration and the weight of the stage increase, the counterweight mechanism and the reaction force cancellation mechanism can also increase in size. This can increase the amount of heat generated by the counterweight mechanism and the reaction force cancellation mechanism and, furthermore, can also increase the size of a surface plate supporting the stage apparatus and the size of an apparatus including the stage apparatus (increase in footprint). Further, in a case of a reaction force cancellation mechanism in which external force is applied to a surface plate, if the reaction force to be cancelled increases, floor vibration caused by the reaction force cancellation mechanism can also increase.

### SUMMARY OF THE INVENTION

The present invention is directed to providing, for example, a stage apparatus, including a plurality of movable stages, advantageous in reducing a size thereof.

According to an aspect of the present invention, a stage apparatus includes first, second, third, and fourth stages and a controller. The first, second, third, and fourth stages are arranged along a plane defined by first and second axes orthogonal to each other, each of the first to fourth stages holding an article and being subjected to scanning along the plane. The controller is configured to control the scanning of the first to fourth stages in synchronization such that a pair of the first and second stages and a pair of the third and fourth stages are respectively positioned symmetrically to each other with respect to the first axis and a pair of the first and third stages and a pair of the second and fourth stages are respectively positioned symmetrically to each other with respect to the second axis.

Further features of the present invention will become apparent from the following description of exemplary embodiments with reference to the attached drawings.

### BRIEF DESCRIPTION OF THE DRAWINGS

FIGS. 1A and 1B illustrate a configuration example of a lithography apparatus (stage apparatus) according to a first exemplary embodiment.

FIGS. 2A and 2B illustrate an operation of a lithography apparatus.

FIG. 3 illustrates a configuration example of a lithography apparatus (stage apparatus) according to a second exemplary embodiment.

FIGS. 4A and 4B illustrate an example of a flow and timing of substrate processing.

FIG. 5 illustrates a configuration example of a lithography apparatus (stage apparatus) according to a third exemplary embodiment.

FIGS. 6A to 6C illustrate an effect of reaction force that has not been cancelled.

### DESCRIPTION OF THE EMBODIMENTS

Various exemplary embodiments, features, and aspects of the invention will be described in detail below with reference to the drawings.

Unless otherwise specified, each member or the like is given the same reference numeral throughout the drawings illustrating the exemplary embodiments, and a repetition of description of each member will be omitted.

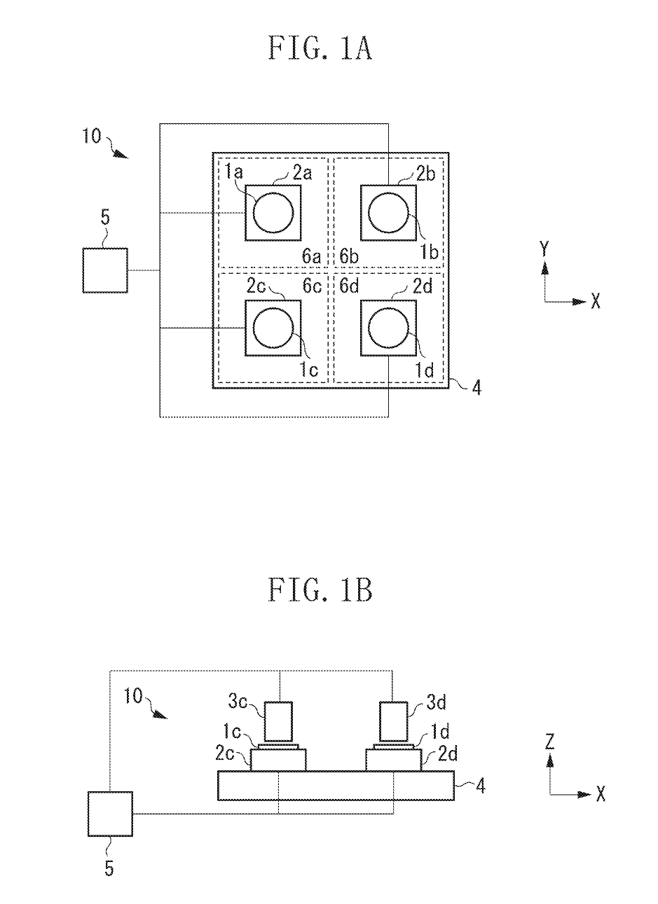

FIGS. 1A and 1B illustrate a configuration example of a lithography apparatus according to a first exemplary embodiment. FIG. 1A is a top view, and FIG. 1B is a front view. While an electron beam lithography apparatus will mainly be described as an example of the lithography apparatus, the lithography apparatus is not limited to the electron beam lithography apparatus. In FIGS. 1A and 1B, a lithography apparatus 10 includes a plurality of electron optical systems (charged-particle optical system) 3a to 3d (in the top view, the electron optical systems 3a to 3d are not illustrated; in the front view, the electron optical systems 3a and 3b are hidden), a plurality of stages 2a to 2d, a stator 4, and a controller 5. The plurality of stages 2a to 2d are respectively capable of supporting and moving (capable of performing a displacing operation or scanning) a plurality of substrates (wafer or article) 1a to 1d. Each of the plurality of electron optical systems 3a to 3d functions as an irradiation device for irradiating a substrate with energy beams for forming a pattern based on pattern data. Operation areas 6a to 6d are where the stages 2a to 2d respectively operate. The controller 5 controls the operation of each stage and can include a position measurement unit for measuring the position of each stage (the position measurement unit may include an interferometer or encoder). The plurality of stages 2a to 2d, the stator 4, and the controller 5 constitute a stage apparatus. Under the control by the controller 5, the lithography apparatus 10 synchronizes electron beam (more generally energy beams) irradiation emitted from the electron optical systems 3a to 3d, with the movement of the stages 2a to 2d to form (draw) a (latent image) pattern on (a resist of) each substrate. Since the controller 5 synchronously controls the positions of the stages as described below, reaction forces resulting from the movements of the stages 2a to 2d for the alignment measurement or the drawing are cancelled by each other. The lithography apparatus 10 can include a vibration control base for supporting the electron optical systems 3a to 3d, the stator 4, or the like and a detection unit (which can include a microscope) for detecting a mark or the like on a substrate to align (measure) the substrate. The lithography apparatus 10 can also include other conventional components such as a vacuum chamber for maintaining a vacuum atmosphere for pattern formation, a substrate conveyer, a drawing data generation unit, etc. In a case in which the lithography apparatus 10 is an electron beam lithography apparatus or an extreme ultraviolet (EUV) lithography apparatus, a pattern can be formed on a resist (photosensitive member) in a vacuum chamber under a high-vacuum environment of, for example, about 10⁻⁴ to 10⁻⁵ Pa or higher.

In the electron beam lithography, a substrate to which a resist has been applied is conveyed to a load lock chamber by the substrate conveyer. To convey the substrate having been exposed to the atmospheric environment into the vacuum chamber under a vacuum environment, the inside of the load lock chamber is vacuum evacuated (exhausted). When the atmospheric pressure in the load lock chamber becomes equal to the atmospheric pressure in the vacuum chamber, the substrate is placed on a stage via a released gate valve. The stage includes a (substrate) chuck for holding a substrate. The chuck can be, but is not limited to, a vacuum chuck, an electrostatic chuck, a water chuck, or the like. The substrate is aligned with respect to the chuck and then held by the chuck. Alternatively, the chuck can be made removable from the stage, and the chuck holding a wafer can be conveyed to the stage. In such a case, the substrate is aligned and then held by the chuck in the chuck chamber, the load lock chamber, or the like, and the substrate and the chuck are conveyed together to the stage by the substrate conveyer. The chuck can be aligned with the stage and then placed on the stage. A method for conveying a substrate to the stage is not limited to that described above, and any other method can also be used.

FIGS. 1A and 1B illustrate a plane stage apparatus as an example. The plane stage apparatus can include, as an actuator, a permanent magnet (movable element) on each stage and a coil (stator 4) on an immovable supporting member (surface plate, etc.). Each stage is capable of performing six-degree-of-freedom displacement by arranging the permanent magnet on each stage and the coil on each stator 4. Alternatively, a permanent magnet can be placed as the stator 4 on the supporting member, and a coil can be placed as the movable element on each stage. The stage apparatus is not limited to the plane stage apparatus, and any other type of stage apparatus can be used. For example, the stage apparatus may include a linear motor for driving in an X-direction and a linear motor for driving in a Y-direction, or may include a fine movement stage on the X-Y stage. The stator 4 can be shared by a plurality of stages or can be provided to each stage.

The single or plurality of stators is supported by the surface plate (supporting member). Thus, when each stage is displaced individually, a reaction force is generated by each stage, which causes the surface plate to vibrate. This vibration can impair the accuracy in stage positioning. Furthermore, if the vibration is transmitted to the electron optical system, the accuracy in electron beam positioning can also be impaired. If each stage individually includes a counterbalancing mechanism or is shared by all stages, the counterbalancing mechanism can cancel reaction forces from the stages to some extent. However, since the mass of and the space for the counterbalancing mechanism are increased, the footprint and the weight of the lithography apparatus 10 can increase. The following describes an arrangement of the lithography apparatus 10 that reduces the foregoing disadvantages.

In the lithography apparatus 10 illustrated in FIGS. 1A and 1B, the four substrates 1a to 1d are respectively placed on the stages 2a to 2d simultaneously or sequentially. Thereafter, the four stages 2a to 2d perform an operation (displacement) to cancel (reduce) the effect of reaction forces generated by the four stages 2a to 2d. This operation can include at least one of an operation for the alignment measurement to obtain information necessary for the positioning of the substrates (measurement operation) and an operation for the formation of a pattern on the substrates (formation operation).

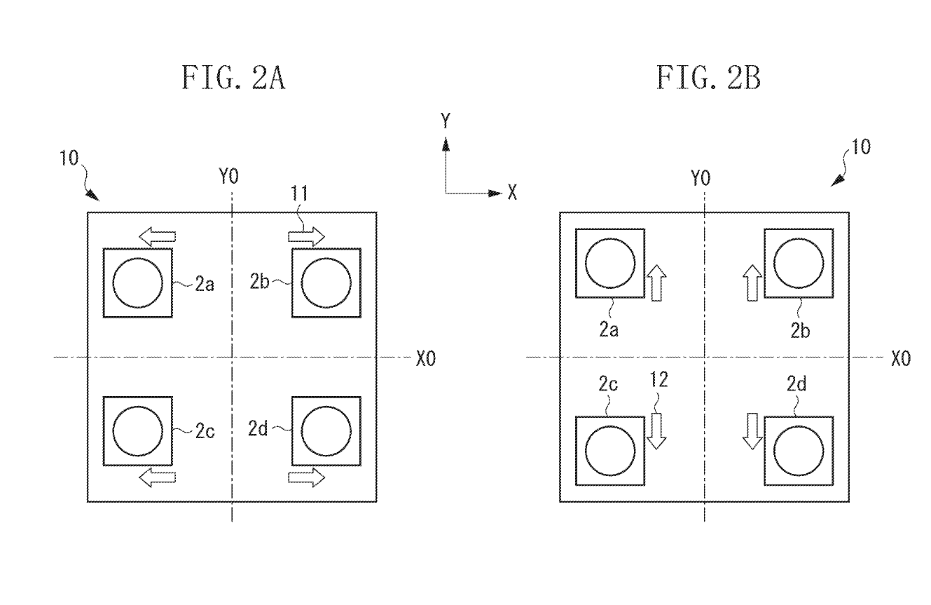

FIGS. 2A and 2B illustrate the operations of the lithography apparatus 10. In FIGS. 2A and 2B, at least one of the measurement operation and the formation operation is performed such that the stages synchronize an operation (displacement) symmetrically about each of the X0 and Y0 axes. The X0 and Y0 axes are first and second axes that are perpendicular to each other and determine (define) an X-Y plane (Cartesian coordinate system in which two axes are perpendicular to each other) when the plane (coordinate system) is set on a surface of the surface plate. The X0 and Y0 axes are respectively parallel to the X and Y axes (refer to FIGS. 2A and 2B) with the origin at the center of gravity of the stator 4. FIG. 2A illustrates the state in which each stage is displaced in the X-direction. FIG. 2B illustrates the state in which each stage is displaced in the Y-direction. By making the foregoing arrangement in which two pairs of stages are always displaced symmetrically about the X0 axis and two pairs of stages are always displaced symmetrically about the Y0 axis, it is possible to cancel (reduce) the effect of reaction forces generated by the four stages. The arrangement enables at least one of the measurement and pattern formation while the reaction forces generated by the four stages are cancelled. Thus, it becomes unnecessary to include a separate counterweight mechanism or a separate reaction force cancellation mechanism. Even if a counterweight mechanism or a reaction force cancellation mechanism needs to be included, only a little capability of them is required. Thus, the foregoing problems can be reduced that relate to the amount of heat generation, an increase in size (footprint), and floor vibration caused by the reaction force cancellation mechanism. Accordingly, a lithography apparatus can be provided that is advantageous in at least one of resolution performance, overlap precision, throughput, and cost of ownership.

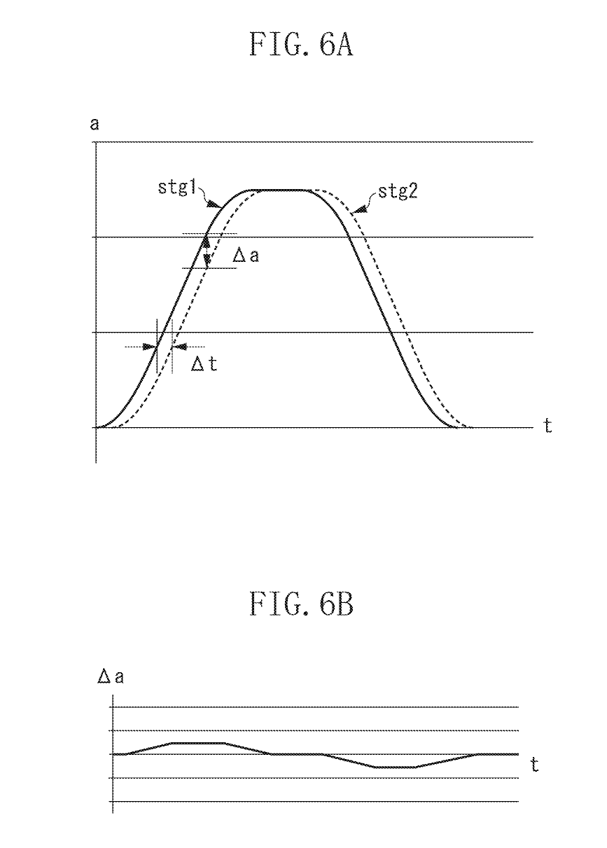

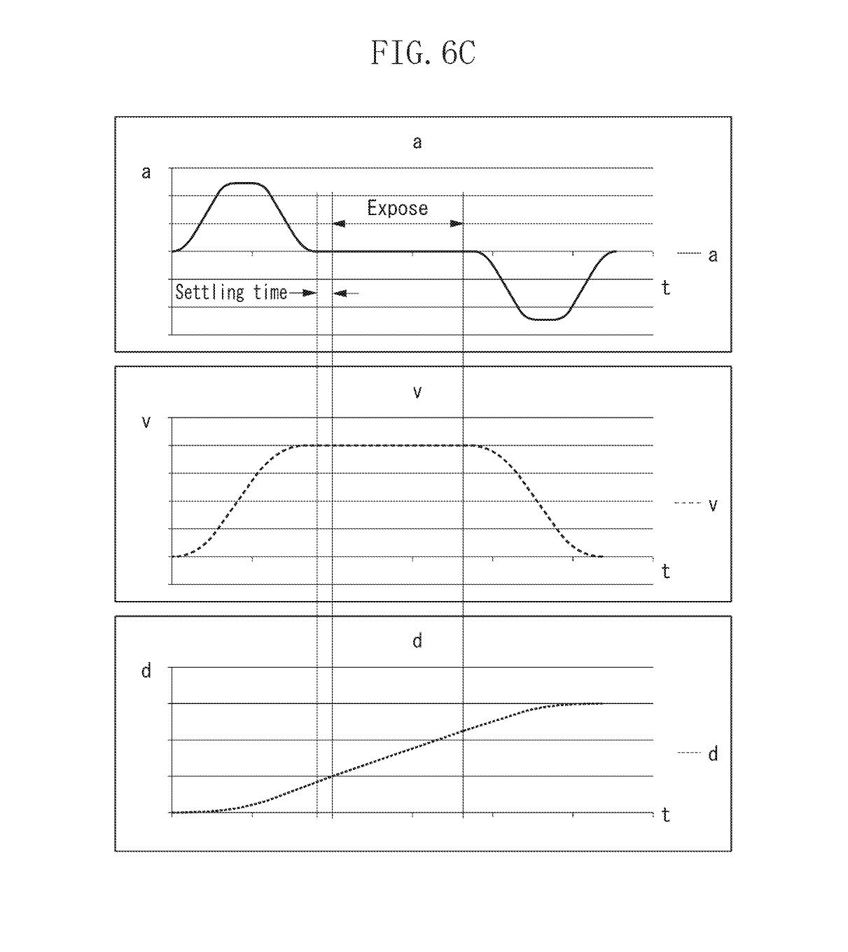

To cancel the reaction forces of the four stages as described above, the four stages are required to have about the same weight (mass). The weight refers to the weight of the entire moving member and includes the weights of a substrate, a chuck, and the like. Further, when the stages synchronize an operation symmetrically about one of the axes (for example, Y0 axis) as described above, temporal changes in the absolute values of accelerations of the stages in the direction of another axis (for example, X0 axis) need to be about the same (a difference between the absolute values needs to be within a tolerance). FIGS. 6A and 6B illustrate an effect of reaction force that has not been cancelled. Specifically, FIGS. 6A and 6B illustrate an effect of reaction force leakage (reaction force that has not been cancelled) in a case in which the accelerations of two stages stg1 and stg2 include a temporal synchronization error Δt. FIG. 6A illustrates an acceleration profile (temporal change) of the stages stg1 and stg2; the stage stg2 has a temporal delay Δt in the absolute value of an acceleration with respect to the stage stg1. FIG. 6B illustrates a temporal change in a difference Δa between the absolute values of accelerations of the stages stg1 and stg2 in the foregoing case. Based on this Δa, the amount of reaction force leakage F is expressed as follows:

F=ΔaΔm

where m represents the mass of each stage.

The foregoing formula is applicable to cases in which there is no difference in weight between two stages. The following formula takes into consideration a difference in weight between the stages stg1 and stg2:

F=F1−F2=(m1×a1)−(m2×a2)

where F1 represents the reaction force of the stage stg1,
F2 represents the reaction force of the stage stg2,
m1 represents the weight of the stage stg1,
m2 represents the weight of the stage stg2,
a1 represents the acceleration of the stage stg1, and
a2 represents the acceleration of the stage stg2.

If such a reaction force leakage occurs, the force F is applied to the stator 4. This can cause vibration and deformation of the stator 4, the surface plate, other supporting members, floor, and the like. This can result in an error in positioning of each stage. For example, vibration transmitted from the stator 4 can cause an error in positioning of another stage. Further, if vibration transmitted to the surface plate, the floor, or the like is transmitted to other components such as the electron optical systems, the position measurement unit for the measurement of the position of the stages, or the detection unit for the alignment measurement, the performance of pattern formation (resolution performance, overlap precision, or throughput) can be impaired.

Hence, to reduce the amount of reaction force leakage described above, it is necessary to equalize the masses of the four stages as much as possible (differences between the masses are within a tolerance) and to increase the synchronization accuracy of the four stages as high as possible. To increase the synchronization accuracy, it is desirable to increase the natural frequency of the structure of the stage apparatus to increase the control responsiveness (following property) of the stages. Another effective structure is a structure that prevents a leaked reaction force applied to the stator 4 from transmitting to other components (unit). For example, it is effective to make arrangement such that a mechanism (vibration control base such as an air mount) for isolation of vibration between a surface plate or the like (structure) supporting the stator 4 and other units or structures, supports the stator 4 or other components. Use of the foregoing arrangements can reduce the effect of reaction force leakage. It is, however, impossible to reduce the effect of reaction force leakage or reaction force to zero. Hence, when the stages or other components vibrate due to reaction force leakage, it is common to set a settling time (waiting time) before initiation of the measurement or the pattern formation until the position of each stage becomes stable. The structure according to the present exemplary embodiment is advantageous in that it can reduce the reaction force leakage to decrease the settling time that affects the throughput.

FIG. 6C illustrates temporal profiles of an acceleration a, a velocity v, and a displacement d of the stages. To increase the throughput, it is effective to reduce both the pattern formation time and other time. For example, the acceleration and the velocity of the stages in the non-pattern-formation-time are increased, and the movement distance in the non-pattern-formation-time is decreased. Furthermore, the velocity of the stages in the pattern formation time is increased. To reduce the pattern formation time, it is also effective to increase the electron beam intensity, resist sensitivity, and the like. In FIG. 6C, the stages are accelerated by a predetermined acceleration profile, and when the velocity of the stages reaches a target velocity, the stages are controlled to maintain a constant velocity. A settling time is set until the state of the stages at the constant velocity stabilizes. After waiting for an end of the vibration of the stages and other components in the settling time, the pattern formation (exposure or patterning) is started. If the amount of reaction force leakage increases, the settling time needs to be increased. However, the structure according to the present exemplary embodiment can be advantageous in terms of throughput, because the structure shortens the settling time and increases as a consequence the ratio of the pattern formation time.

While the lithography apparatus 10 illustrated in FIGS. 1A and 1B include one stator 4 shared by four stages, the lithography apparatus is not limited to the lithography apparatus 10. For example, it is possible to use a so-called cluster lithography apparatus that discretely includes a plurality of combinations of one electron optical system and one stage. In this case, if the plurality of stages synchronizes an operation (displacement) symmetrically as described above, the effect of reaction force of the plurality of stages can be reduced (for example, the reaction force transmits to the floor and then is cancelled).

The structure of the electron optical system is not particularly limited. For example, a plurality of electron optical systems (multicolumn) can perform processing in parallel on a single substrate, or a single electron optical system (single column) can process a substrate with a plurality of electron beams. As to the lithography apparatus, while the foregoing describes the electron beam lithography apparatus as an example, the lithography apparatus is not limited to the electron beam lithography apparatus. A lithography apparatus that forms a pattern under an atmospheric environment or in an atmosphere of a specific gas can also be used. The stage apparatus according to the present exemplary embodiment is applicable to any apparatus other than lithography apparatuses that includes the stage apparatus such as various types of measurement apparatuses and processing apparatuses.

As the foregoing describes, the present exemplary embodiment can provide a stage apparatus that reduces the effect of reaction forces of a plurality of stages. Hence, the present exemplary embodiment can provide a lithography apparatus that is advantageous in at least one of resolution performance, overlap precision, and throughput.

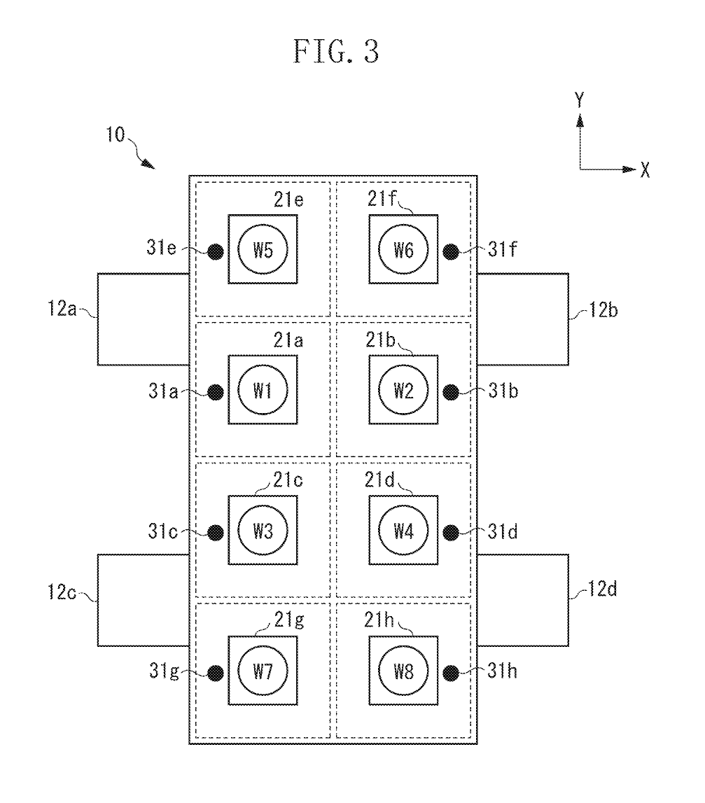

FIG. 3 illustrates an example of the structure of a lithography apparatus according to a second exemplary embodiment. The lithography apparatus 10 includes eight stages 21a to 21h capable of supporting and moving eight substrates W1 to W8, respectively. The lithography apparatus 10 also includes eight detection units 31a to 31h for alignment measurement that respectively correspond to the eight stages. The lithography apparatus 10 further includes four conveyers 12a to 12d. Each of the conveyers can include a load lock chamber, a chuck chamber for attaching or removing a substrate to or from a chuck, and the like. In the present exemplary embodiment, four stages among the eight stages make one pair (one set). For example, the stages 21a to 21d make a pair, and the stages 21e to 21h make another pair. Then, each pair of stages synchronizes an operation.

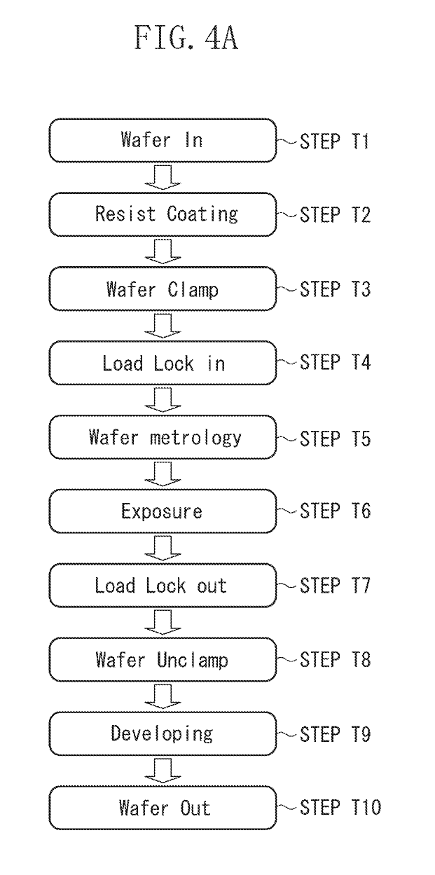

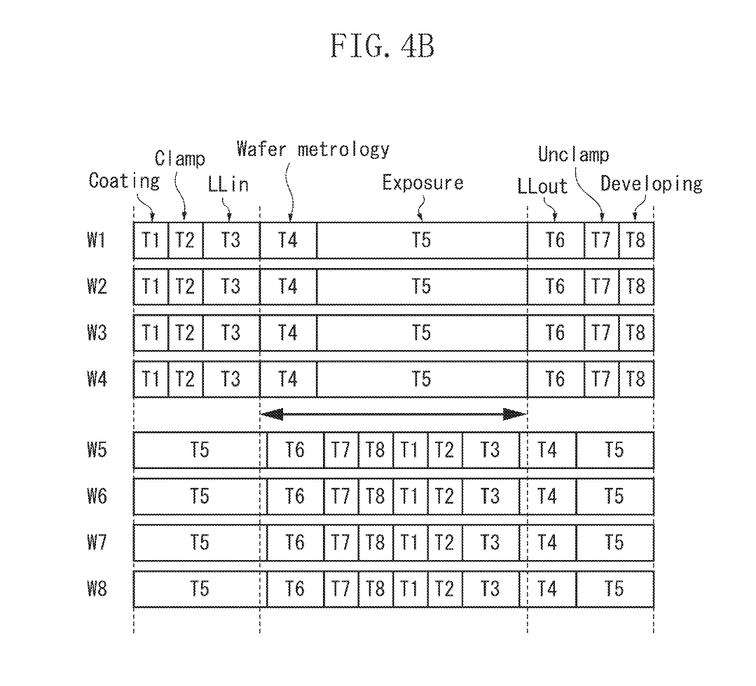

The substrates W1, W2, W3, and W4 are respectively conveyed by the conveyers 12a, 12b, 12c, and 12d to the stages 21a, 21b, 21c, and 21d in parallel. Then, the stages 21a to 21d synchronize an operation (displacement) to first measure the alignment and then form the pattern on the respective substrates. The synchronous operations are similar to those in the first exemplary embodiment. While the above substrates are conveyed, the stages 21e to 21h synchronize an operation to measure the alignment and form the pattern. After the conveyance is finished, the substrates are respectively removed from the stages 21e to 21h by the conveyers 12e to 12h. The foregoing operations are desirably similar to those illustrated in FIGS. 4A and 4B. FIGS. 4A and 4B illustrate an example of a flow and timing of substrate processing. FIG. 4A illustrates an example of a flow of processing on a single substrate. In step T1, a coater (coating apparatus) applies a resist on the substrate. In step T2, the chuck chamber clamps the substrate to the chuck. In step T3, the chuck holding the substrate is conveyed into the load lock chamber, and the load lock chamber is vacuum evacuated. Thereafter, the substrate is conveyed to the stage and supported by the stage. In step T4, the alignment or the like is measured on the substrate. In step T5, the pattern is formed. In step T6, the substrate having undergone the pattern formation is conveyed into the load lock chamber, and the load lock chamber is returned to the atmospheric pressure, followed by removal of the substrate from the load lock chamber. In step T7, the chuck chamber unclamps the substrate from the chuck. In step T8, a developer (developing apparatus) performs development processing on the substrate.

FIG. 4B illustrates an example of a process chart in which among the eight substrates W1 to W8, the substrates W1 to W4 are processed as one pair, and the substrates W5 to W8 are processed as another pair. According to the process chart, while the substrates W1 to W4 undergo the measurement (step T4) and the pattern formation (step T5), the substrates W5 to W8 undergo the processing from the removal or the conveyance of the load lock chamber (steps T6 to T3). This enables high-throughput processing without (or with (a) little) waiting time (temporal loss). If waiting time arises, an adjustment can be made, such as increasing the number of units for the processing from steps T6 to T3, to minimize the waiting time as small as possible.

While the number of pairs of the stages and the detection units is eight in the present exemplary embodiment, the number of pairs is not limited to eight and can be any multiple of four. If the number of stages that synchronizes an operation is a multiple of four, the number of stages provided does not necessarily have to be a multiple of four. For example, if six stages are provided, four stages among the six stages can synchronize an operation while the remaining two stages can be in a stopped state or an operation in which the reaction forces generated by the two stages do not affect the other processing.

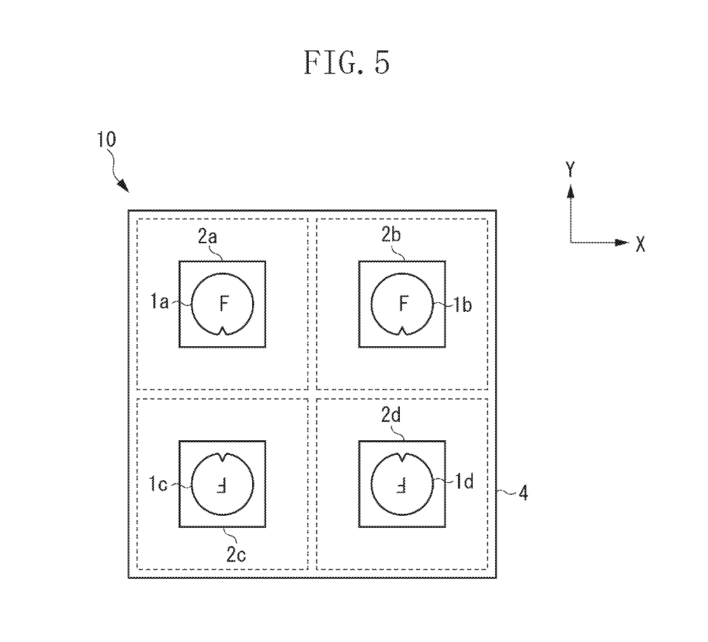

FIG. 5 illustrates a structural example of a lithography apparatus according to a third exemplary embodiment. The following describes an aspect of the pattern formation in the lithography apparatus 10 according to the present exemplary embodiment, with reference to FIG. 5. In the lithography apparatus 10, the stages 2a to 2d respectively supporting the substrates 1a to 1d are provided on the stator 4. The character “F” specified on each substrate schematically indicates a pattern formed (or to be formed) on the substrate. Further, an indentation of each substrate indicates a notch. While the substrates have a notch in the present exemplary embodiment, the substrates may have an orientation flat. In general, the orientation of the substrate is likely to be determined based on the position of the notch. Hence, FIG. 5 illustrates the notches and the patterns (“F”) such that the positions of the notches are consistent with the orientations of the patterns (“F”).

The present exemplary embodiment describes both cases in which the same pattern “F” is formed on the four substrates and in which different patterns are formed on the four substrates. In the case in which the same pattern “F” is formed on the four substrates, since the drawing data is the same, the amount of data transfer is ¼ compared with the cases in which different patterns are formed on the four substrates. Thus, the load of data transfer can be reduced significantly. In the pattern formation, each stage can perform the operation (displacement) according to the position of electron beam irradiation on the substrate by the electron optical system, the position of the substrate on the stage, and the drawing procedure.

The present exemplary embodiment employs the following drawing procedure. First, a stripe area extending in the X-direction on the substrate is drawn through one continuous scanning by the stage. Then, the stage is one step moved in the Y-direction without drawing by a width that is about the same as the width of the stripe area. Thereafter, another stripe area extending in the X-direction on the substrate is drawn through one continuous scanning by the stage. The foregoing procedure is repeated. The distance of the stepping movement is desirably a longest distance possible to an extent that the pattern connection accuracy is satisfied so that the distance is not disadvantageous in terms of throughput. Furthermore, the distance is desirably determined also based on distribution of the amount of correction between the drawing pattern correction by deflection of the electron beams and the drawing pattern correction by correction of pattern data, etc. If an overlap error between the stripe areas connected (overlapped) together in the Y-direction increases, a drawing pattern can be defective. Hence, an adequately high overlap precision is required.

The following describes an example of the drawing procedure on the substrate 1a in FIG. 5. On an upper surface (surface) of the substrate 1a, the upper left position (−X, Y0) in the sheet is determined as a drawing start position. It is assumed that a drawing end position is determined as (+X, Y0) when the stage performs one scanning in the −X-direction. The stage makes steps n times (n is natural number) in the +Y-direction to draw over the entire surface of the substrate. It is assumed that the next drawing start position is determined as (+X, Y1) when the stage makes one step in the +Y-direction. Then, the drawing end position in a case in which the stage draws over the entire surface of the substrate is (+X, Yn) or (−X, Yn). Accordingly, the drawing procedure on the substrate 1a for each stripe area can be represented by (−X, Y0), (+X, Y0), (+X, Y1), (−X, Y1), (−X, Y2) . . . as a repeat of the drawing start position and the drawing end position described above. While the substrate 1a is drawn in that way, the substrate 1b is synchronously drawn as follows: (+X, Y0), (−X, Y0), (−X, Y1), (+X, Y1), (+X, Y2) . . . . Similarly, the substrate 1c is synchronously drawn as follows: (−X, Yn), (+X, Yn), (+X, Yn−1), (−X, Yn−1), (−X, Yn−2) . . . . Similarly, the substrate 1d is synchronously drawn as follows: (+X, Yn), (−X, Yn), (−X, Yn−1), (+X, Yn−1), (+X, Yn−2) . . . . Accordingly, the pair of the stages 2a and 2b and the pair of the stages 2c and 2d are displaced symmetrically about the Y0-axis (FIGS. 2A and 2B) on the same Y0 coordinate. Further, the pair of the stages 2a and 2c and the pair of the stages 2b and 2d are displaced symmetrically about the X0-axis (FIGS. 2A and 2B) on the Y0 coordinates with different signs and the same absolute value. In other words, a drawing data sequence for the pair of the substrates 1a and 1b is different from (opposite to) that for the pair of the substrates 1c and 1d, whereas the pair of the substrates 1a and 1d and the pair of the substrates 1b and 1c have the same drawing data sequence.

According to the foregoing exemplary embodiment, the controller 5 only needs to prepare (generate) two types of pattern data that are opposite to each other in the data sequence in the X-direction. Simply by doing this, the same pattern can be formed on the four substrates while the stages are synchronously displaced (scanning), enabling highly-precise pattern formation with a reduced effect of reaction forces of the stages.

The foregoing procedure is a mere example, and the procedure is not limited to the foregoing procedure. Examples of other possible procedures include a procedure in which the pattern is formed only when the stages are scanning in one direction in the X-direction and a procedure in which the pattern formation and the stepping movement are repeated for each shot area.

A case is described where different patterns are respectively formed on four substrates. In this case, the stages can be displaced synchronously by the same scanning and stepping procedure to form the pattern regardless of each shot layout. When the pattern is formed by the same procedure, there may be a substrate that has an area on which no pattern formation is necessary, e.g., a part of a shot includes a blank pattern. In this case, it is still important to perform a dummy operation to continuously synchronize the operations of the stages. Further, all the stages can synchronize the operation by a drawing procedure designed for the substrate required to be drawn with the highest accuracy among the four substrates. Further, in a case in which the pattern is formed only on three or fewer substrates, if a stage that does not form the pattern synchronizes an operation (dummy operation) with the other stages that form the pattern, the effect of reaction forces of the stages can be reduced.

As the foregoing describes, the structure according to the present exemplary embodiment can reduce the effect of reaction forces of the stages in both cases in which the same pattern is formed on the four substrates and in which different patterns are formed on the respective four substrates. Thus, the structure according to the present exemplary embodiment is advantageous in at least one of resolving power, overlapping performance, and throughput.

A method of manufacturing an article according to an exemplary embodiment of the present invention is suitable for manufacturing an article such as a micro device, e.g., semiconductor device, and a device having a fine structure. The method of manufacturing an article according to the present exemplary embodiment includes forming a latent image pattern by use of a lithography apparatus on a photosensitive material applied to a substrate (forming a pattern on a substrate) and developing the substrate on which the latent image pattern is formed (developing the substrate on which the pattern is formed). The manufacturing method may further include other conventional treatments (oxidation, film forming, deposition, doping, planarization, etching, resist separation, dicing, bonding, packaging, etc.). The method of manufacturing an article according to the present exemplary embodiment is advantageous in at least one of performance, quality, productivity, and production cost of the article, compared with conventional methods.

### Other Embodiments

Embodiments of the present invention can also be realized by a computer of a system or apparatus that reads out and executes computer executable instructions recorded on a storage medium (e.g., non-transitory computer-readable storage medium) to perform the functions of one or more of the above-described embodiment(s) of the present invention, and by a method performed by the computer of the system or apparatus by, for example, reading out and executing the computer executable instructions from the storage medium to perform the functions of one or more of the above-described embodiment(s). The computer may comprise one or more of a central processing unit (CPU), micro processing unit (MPU), or other circuitry, and may include a network of separate computers or separate computer processors. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-096011 filed Apr. 30, 2013, which is hereby incorporated by reference herein in its entirety.

What is claimed is:

1. A stage apparatus comprising:
first, second, third, and fourth stages arranged along a plane defined by first and second axes orthogonal to each other, each of the first to fourth stages holding an article and being subjected to scanning along the plane; and
a controller configured to control the scanning of the first to fourth stages in synchronization such that a pair of the first and second stages and a pair of the third and fourth stages are respectively positioned symmetrically to each other with respect to the first axis and a pair of the first and third stages and a pair of the second and fourth stages are respectively positioned symmetrically to each other with respect to the second axis.

2. The apparatus according to claim 1, wherein the controller is configured to control the scanning such that the two stages that are positioned symmetrically to each other with respect to one of the first and second axes have the same absolute value of an acceleration in a direction of the other of the first and second axes.

3. The apparatus according to claim 1, wherein the apparatus is configured such that the first to fourth stages have the same weight.

4. The apparatus according to claim 1, wherein the first to fourth stages are supported by a structure common thereto.

5. The apparatus according to claim 4, further comprising an actuator including a stator and configured to displace the first to fourth stages,
wherein the stator is supported by the structure.

6. A lithography apparatus comprising:
a stage apparatus defined in claim 1,
wherein the lithography apparatus is configured to perform processing of pattern formation in synchronization on a plurality of articles respectively held by a plurality of stages included in the stage apparatus.

7. The lithography apparatus according to claim 6, wherein the processing includes at least one of the pattern formation and measurement with respect to the articles.

8. The lithography apparatus according to claim 6, further comprising a plurality of conveyers configured to convey the articles with respect to the first to fourth stages.

9. The lithography apparatus according to claim 6, further comprising a plurality of irradiation devices each configured to irradiate one of the articles with an energy beam for the pattern formation based on pattern data.

10. The lithography apparatus according to claim 9, wherein the plurality of conveyers is configured to convey the articles such that two articles that are respectively held by two stages positioned symmetrically to each other with respect to one of the first and second axes are oriented symmetrically with respect to the one of the first and second axes.

11. The lithography apparatus according to claim 10, wherein the controller is configured to generate two types of the pattern data with data sequences different from each other with respect to the four articles respectively held by the first to fourth stages.

12. A method of manufacturing a product, the method comprising:
forming a pattern on an article by use of a lithography apparatus;
developing the article on which the pattern has been formed; and
processing the developed article to manufacture the product,
wherein the lithography apparatus includes a stage apparatus, the stage apparatus including:
first, second, third, and fourth stages arranged along a plane defined by first and second axes orthogonal to each other, each of the first to fourth stages holding an article and being subjected to scanning along the plane; and
a controller configured to control the scanning of the first to fourth stages in synchronization such that a pair of the first and second stages and a pair of the third and fourth stages are respectively positioned symmetrically to each other with respect to the first axis and a pair of the first and third stages and a pair of the second and fourth stages are respectively positioned symmetrically to each other with respect to the second axis,
wherein the lithography apparatus is configured to perform processing of pattern formation in synchronization on a plurality of articles respectively held by a plurality of stages included in the stage apparatus.
